(19) United States
(12) Patent Application Publication
(10) Pub. No.: US 2014/0335683 A1
(43) Pub. Date: Nov. 13, 2014

(54) METHOD FOR PRODUCING GALLIUM NITRIDE

(71) Applicant: National Taiwan University, Taipei (TW)

(72) Inventors: CHING-FUH LIN, Taipei (TW); Chun-Wei Ku, Taipei (TW); Hao-Yu Wu, Taipei (TW)

(73) Assignee: National Taiwan University, Taipei (TW)

(21) Appl. No.: 14/021,108

(22) Filed: Sep. 9, 2013

(30) Foreign Application Priority Data
May 13, 2013 (TW) 102116894

(51) Int. Cl. H01L 21/02

(52) U.S. Cl. CPC H01L 21/0254; H01L 21/0262; H01L 21/02472
USPC 438/492

(57) ABSTRACT

A method for producing a gallium nitride layer using a pulsed laser is disclosed. The method includes (1) providing a substrate; (2) forming a zinc oxide layer on the substrate; and (3) forming a gallium nitride thin film on the zinc oxide layer by pulsed laser deposition (PLD).

### BACKGROUND OF THE INVENTION

1. Field of the Invention

The present invention relates to a method for producing gallium nitride and application thereof, and more particularly relates to a method for producing gallium nitride by pulsed laser deposition.

2. Description of the Prior Art

With the rapid development of technology and the growing global environmental awareness, high-efficiency light emitting diodes (LEDs) have become popular. Especially, the gallium nitride LEDs have been extensively studied and applied.

There are two most widely-used methods to fabricate gallium nitride LEDs:

(1) One method is to grow the nitride epitaxial crystal layer on the sapphire substrate by MOCVD, and then the nitride epitaxial crystal layer is bonded with the metal/silicon. Afterwards, the laser is used to lift off the nitride epitaxial crystal layer from the sapphire substrate. However, the large lattice constant mismatch between sapphire and gallium nitride leads to high dislocation density in the gallium nitride epitaxial crystal layer, which may reduce the charge carrier mobility and the minority carrier lifetime and decrease the thermal conductivity, so as to degrade the performance. Therefore, the size of the sapphire substrate is very limited in the fabricating process, and the sapphire substrate larger than 4 inches is still in a low yield. Furthermore, the cost of laser lift off is also high.

(2) The other method is to fabricate the patterned silicon substrate first, and then the nitride buffer layer is fabricated on the patterned silicon substrate by MOCVD. Afterwards, the nitride light emitting elements are fabricated by the MOCVD. Although this method may fabricate large scale light emitting elements, however the silicon substrate may absorb the light, resulting in a low luminance.

Accordingly, a need has thus arisen to propose a novel method of producing the gallium nitride film to overcome disadvantages of the conventional fabricating methods.

### SUMMARY OF THE INVENTION

In view of the foregoing, it is an object of embodiments of the present invention to provide a method for producing a gallium nitride layer.

According to one embodiment of the present invention, the method includes following steps: providing a substrate; forming a zinc oxide layer on the substrate; and forming a gallium nitride thin film on the zinc oxide layer by pulsed laser deposition (PLD).

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 to FIG. 7 are a series of drawings illustrating a method for producing gallium nitride in accordance with an embodiment of the present invention.

### DESCRIPTION OF THE PREFERRED EMBODIMENT

A detailed description of the present invention will be discussed in the following embodiments, which are not intended to limit the scope of the present invention and which can be adapted for other applications. While drawings are illustrated in detail, it is appreciated that the quantity of the disclosed components may be greater or less than that disclosed, except expressly restricting the amount of the components.

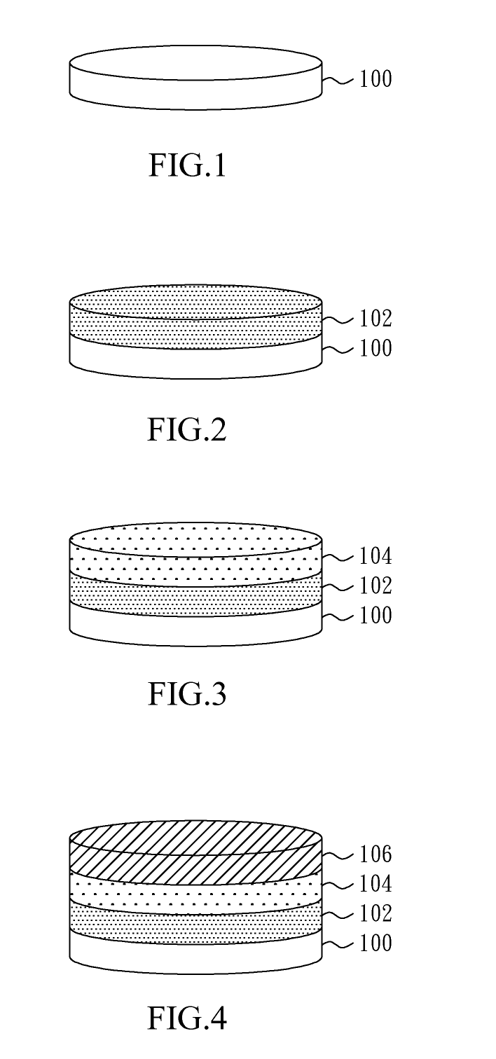

FIG. 1 to FIG. 4 show a method for producing gallium nitride on zinc oxide in accordance with an embodiment of the present invention; they are a series of drawings illustrating the process of this method and different steps of this method. Referring to FIG. 1A, firstly, a substrate 100 is provided wherein the substrate 100 is metal, silicon (Si), quartz, glass, sapphire, or polyethylene terephthalate (PET). The substrate 100 is cleared by acetone or methanol, and then the substrate 100 is washed by deionized water and is blown for drying.

Referring to FIG. 2, a zinc oxide layer 102 is formed on the substrate 100, being regarded as a buffer layer. The zinc oxide layer 102 may be formed on the substrate 100 by atomic layer deposition, electrochemical deposition, pulsed laser deposition, metalorganic chemical vapor deposition or hydrothermal method. Meanwhile, the thickness of the zinc oxide layer 102 (i.e. the predetermined thickness) is 0.1 μm to 10 μm, but different thickness of the zinc oxide thin layer 102 can be chosen or determined according to requirements of this process or following processes.

Then, referring to FIG. 3, Pulsed Laser Deposition (PLD) is utilized to form a gallium nitride thin film 104 on the zinc oxide layer 102. Furthermore, in one embodiment, PLD may be implemented in a gas environment containing a nitrogen source, such as nitrogen gas, in order to form the gallium nitride thin film 104, and the gas flow rate can be adjusted according to the critical process conditions and requirements. Then, when PLD is being implemented, a chamber pressure may be between 0.001 Torr to 760 Torr. Moreover, while the gallium nitride thin film 104 is being formed, the substrate of PLD can be heated to be 30 to 1000, and the accurate required temperature may be adjusted according to the critical process conditions. Furthermore, a working distance of PLD, which is the distance between the substrate and a target, can be 15 cm to 30 cm. Meanwhile, a laser energy of PLD may be adjusted to be 200 mJ/pulse to 600 mJ/pulse according to the actual process conditions, and a laser frequency of PLD may be adjusted to be 5 Hz to 100 Hz. Therefore, when PLD is used to produce the gallium nitride thin film 104, the gallium nitride thin film 104 can be formed on the zinc oxide layer 102 with a required thickness and properties by choosing the appropriate gas environment and adjusting the suitable gas flow rate, the heated temperature of the substrate, and the laser energy and frequency of PLD.

Referring to FIG. 4, in one embodiment, after the gallium nitride thin film 104 is formed, a step of forming an optical element on the gallium nitride thin film is then proceeded. The gallium nitride thin film 104 is used as a epitaxial center to form or grow one layer or multiple layers of nitride semiconductor crystal or nitride epitaxial crystal 106 on the gallium nitride thin film 104 for forming optical elements (or photoelectric elements), for example the light emitting diode (LED) being formed on the gallium nitride thin film 104. The number of the layers of the nitride semiconductor crystal or the nitride epitaxial crystal 106 is determined by the kind and the structure of the desired optical elements (or photoelectric elements). The nitride semiconductor crystal or the nitride epitaxial crystal 106 may be formed by atomic layer deposition, electrochemical deposition, pulsed laser deposition, or metalorganic chemical vapor deposition.

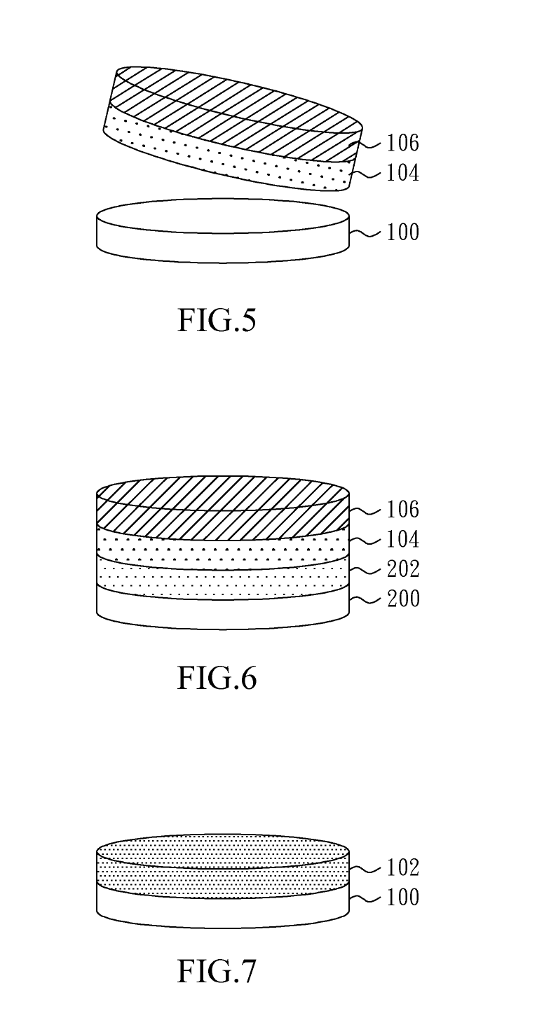

Referring to FIG. 5, in another embodiment, after the nitride semiconductor crystal or nitride epitaxial crystal 106 is formed, the zinc oxide layer 102 is then etched by chemical etching method for removing the gallium nitride thin film 104 from the substrate 100. Particularly, the zinc oxide layer 102 is etched by a chemical etching solution such that the nitride semiconductor crystal or nitride epitaxial crystal 106, which is formed on the gallium nitride thin film 104, may be completely separated from the substrate 100 or the zinc oxide layer 102. That is to say, all of the zinc oxide layer 102 is etched, and therefore the optical element(s) (or photoelectric element(s)) constructed on the zinc oxide layer 102 may be separated from the substrate 110. The chemical etching solution used for etching the zinc oxide layer 102 may include an acid solution, which can be a hydrochloric acid, acetic acid, sulfuric acid, nitric acid, or mixed solution of two or more of these acids. Different concentrations of the acid solution can be determined or chosen to etch the zinc oxide layer according to the requirements of the process. For example, the concentrations of the acid solution is determined or chosen according to the desired etching rate or etching time.

Referring to FIG. 6, the gallium nitride thin film 104 and the nitride semiconductor crystal or the nitride epitaxial crystal 106, which are lifted off in the removing step, are transferred on another substrate, such as a silicon substrate. In the transferring step, a metal layer 202 is firstly coated on the substrate 200 as a light reflective layer, so that the gallium nitride thin film 104 may be transferred to the metal layer 202 formed on the substrate 200.

Finally, referring to FIG. 7, the substrate 100 is recycled to produce the optical element(s) (or photoelectric element(s)) again. Consequently, the steps illustrated in FIG. 1 to FIG. 5 are repeated or performed to form the zinc oxide layer 102 on the substrate 100, and to form the gallium nitride thin film 104 on the zinc oxide layer 102, and to form one layer or multiple layers of nitride semiconductor crystal or nitride epitaxial crystal 106 on the gallium nitride thin film 104, and to remove the zinc oxide layer 102, and to recycle the substrate 100 for producing the optical element(s) (or photoelectric element(s)) until the substrate 100 cannot be used anymore. Therefore, the substrate 100 can be recycled to greatly reduce the cost of fabricating process.

By applying the method illustrated above, the zinc oxide layer may be fabricated as the buffer layer on different substrates. Then, other epitaxial layers can be deposited on the zinc oxide layer by PLD to make optoelectronic devices. After depositing epitaxial layers, the zinc oxide layer can be lifted off by the acidic aqueous. Therefore, the substrate can be recycled to grow the buffer layers. Accordingly, the large-area gallium nitride thin film may be repeatedly and efficiently formed on the substrate, and the low cost and high efficiency to the production demand can be achieved simultaneously.

Although specific embodiments have been illustrated and described, it will be appreciated by those skilled in the art that various modifications may be made without departing from the scope of the present invention, which is intended to be limited solely by the appended claims.

What is claimed is:

1. A method for producing a gallium nitride, comprising:
(1) providing a substrate;
(2) forming a zinc oxide layer on the substrate; and
(3) forming a gallium nitride thin film on the zinc oxide layer by pulsed laser deposition (PLD).

2. The method of claim 1, wherein the substrate is metal, silicon (Si), quartz, glass, sapphire, or polyethylene terephthalate (PET).

3. The method of claim 1, wherein the step (2) is performed by atomic layer deposition, electrochemical deposition, pulsed laser deposition, metalorganic chemical vapor deposition or hydrothermal method.

4. The method of claim 1, wherein a thickness of the zinc oxide thin film is 0.1 μm to 10 μm.

5. The method of claim 1, wherein the substrate of the step (3) is performed at 30 to 1000 by pulsed laser deposition.

6. The method of claim 1, wherein in the step (3), a working distance of PLD is 15 cm to 30 cm.

7. The method of claim 1, wherein in the step (3), PLD is implemented in a gas environment containing a nitrogen source.

8. The method of claim 1, wherein in the step (3), a laser energy of PLD is 200 mJ/pulse to 600 mJ/pulse.

9. The method of claim 1, wherein in the step (3), a laser frequency of PLD is 5 Hz to 100 Hz.

10. The method of claim 1, further comprising a step of forming an optical element on the gallium nitride thin film, and the gallium nitride thin film is used to be an epitaxial center for forming a semiconductor crystal or epitaxial crystal.

11. The method of claim 10, wherein the step of forming an optical element on the gallium nitride thin film is performed by atomic layer deposition, electrochemical deposition, pulsed laser deposition, or metalorganic chemical vapor deposition.

12. The method of claim 1, further comprising a removing step, wherein the removing step is performed by chemical etching method to remove the zinc oxide layer, and then the gallium nitride thin film is separated from the substrate.

13. The method of claim 12, wherein the zinc oxide layer is etched by a chemical etching solution for removing the zinc oxide layer, and the chemical etching solution comprises an acid solution.

14. The method of claim 13, wherein the acid solution is a hydrochloric acid, acetic acid, sulfuric acid, nitric acid, or mixed solution of said acids.

15. The method of claim 13, wherein an etching time of the zinc oxide layer is determined by a concentration of the acid solution.

16. The method of claim 12, further comprising:
recycling the substrate to repeat the steps (1)-(3) and the removing step for producing the gallium nitride thin film repeatedly.
